(19) United States
(12) Patent Application Publication
(10) Pub. No.: US 2007/0181889 A1
(43) Pub. Date: Aug. 9, 2007

(54) Semiconductor light emitting device and method for manufacturing the same

(76) Inventor: Kenji Orita, Osaka (JP)

Correspondence Address: MCDERMOTT WILL & EMERY LLP, 600 13TH STREET, NW, WASHINGTON, DC, 20005-3096, US

(21) Appl. No.: 11/703,646

(22) Filed: Feb. 8, 2007

(30) Foreign Application Priority Data
Feb. 8, 2006 (JP) 2006-031024

(51) Int. Cl. H01L 33/00; H01L 31/12; H01L 27/15; H01L 29/26

(52) U.S. Cl. 257/79

(57) ABSTRACT

A semiconductor light emitting device comprises a semiconductor multilayer film including an active layer for generating light, a p electrode formed on the semiconductor multilayer film, and a plasmon generating layer, which are provided on a substrate. A portion of the semiconductor multilayer film including at least the active layer forms a plurality of rods. The plasmon generating layer (8) fills between each rod. The plasmon generating layer (8) is formed of a material having a negative dielectric constant at the wavelength of emitted light. The rods are arranged in a periodic manner.

### BACKGROUND OF THE INVENTION

1. Field of the Invention

The present invention relates to a light emitting device employing a semiconductor and a method for manufacturing the light emitting device.

2. Description of the Related Art

Of semiconductor light emitting devices, Light Emitting Diodes (LEDs) are easier to manufacture and control than semiconductor lasers, and are expected as low-cost light sources for illumination and communication. However, LEDs have problems, such as a low external quantum efficiency, a poor directivity of emitted light, and the like. As used herein, the “external quantum efficiency” refers to an efficiency with which implanted carriers produce light obtained outside an LED.

There are two factors responsible for the low external quantum efficiency. One factor is a low internal quantum efficiency (efficiency with which implanted carriers can be converted into photons), and the other factor is a low light extraction efficiency (efficiency with which light generated inside an LED can be obtained outside the LED).

The internal quantum efficiency increases with a decrease in the number of defects in semiconductor crystal which emits light. In LEDs whose active layer is made of a semiconductor material, such as AlGaAs, AlInGaP, InGaN, or the like, and emit infrared light, red light, blue light or the like, their internal quantum efficiencies can be caused to be close to 100% by designing the crystal growth of the semiconductor. However, in green and ultraviolet LEDs and the like, it is difficult to grow semiconductor crystal, and their internal quantum efficiencies remain low.

Conventionally, when crystal growth is performed on Si substrates, it is expected that manufacturing cost will be reduced by increasing the diameter of wafers. However, when crystal of a semiconductor material which does not have a lattice-match with Si is grown on a substrate made of Si or the like, high-density defects occur in the semiconductor crystal, resulting in low internal quantum efficiency.

On the other hand, an improvement in light extraction efficiency does not depend on the wavelength of emitted light and is a general challenge to LEDs. The reason for low light extraction efficiency is that light generated in a semiconductor having a high refractive index is totally reflected at an interface of the semiconductor and the air having a low refractive index, so that the light is confined within the LED. The confined light is eventually absorbed by the electrode, the substrate, and the like, i.e., is wasted as heat.

Also, light emitted by LEDs typically has an angle of radiation with a full width at half maximum of as large as ±50 degrees. This is because light is emitted from LEDs by spontaneous emission. Light generated by spontaneous emission is emitted in substantially all directions in space.

As a method for improving the external quantum efficiency, Document 1 (K. Okamoto, et. al, Nature Materials, vol. 3, pp. 601, 2004) and the like propose use of surface plasmons. FIG. 17A is a diagram for describing surface plasmons. FIG. 17B is a graph for describing surface plasmons.

The plasmon results from quantization of plasma oscillation, which is collective response of free electrons in a metal or the like. The surface plasmon is a kind of electromagnetic waves which result from coupling of a plasmon with a photon and is localized in a minute area of a surface or an interface of a semiconductor device. As illustrated in FIG. 17A, electromagnetic waves can be localized at an interface of a substance having a negative dielectric constant, such as a metal or the like, and a substance having a positive dielectric constant, such as a dielectric substance. This is the surface plasmon. A region where surface plasmons occurs has a length of several tens of nanometers on the metal side and about 100 nm on the dielectric substance side (in the visible region) in a direction normal to the interface.

A dispersion relation between a frequency ω, and a wave number k_{//} in a direction parallel to the interface between a metal and a dielectric substance, of a surface plasmon is roughly illustrated in FIG. 17B. The dispersion curve asymptotically approaches a line of ω=ωp/√(εm+ε) when k_{//} is large, where εm represents the dielectric constant of the metal (a substance having a negative dielectric constant), ε represents the dielectric constant of the dielectric substance (a substance having a positive dielectric constant), and ωp represents the natural frequency of a bulk plasmon.

A major factor responsible for a decrease in the internal quantum efficiencies of LEDs is crystal defects in the active layer as described above. A predetermined time is required for an electron-positive hole pair which is formed in the active layer by implantation of positive holes and electrons to undergo radiative recombination due to spontaneous emission. During the time, an electron-positive hole pair captured by a crystal defect undergoes nonradiative recombination and loses an energy of h/2πω. The internal quantum efficiency ηᵢₙₜ is represented by:

$${η}_{int} = \frac{1 / {τ}_{r}}{1 / {τ}_{r} + 1 / {τ}_{nr}} \qquad ( 1 )$$

where 1/τ represents the rate of radiative recombination and 1/τₙᵣ represents the rate of nonradiative recombination.

The expression means that, as the number of crystal defects increases, nonradiative recombination occurs in a shorter time τₙᵣ, i.e., 1/τₙᵣ for generating nonradiative recombination increases, so that the internal quantum efficiency ηᵢₙₜ decreases.

The key to improve the internal quantum efficiency due to surface plasmons is to transfer the energy of h/2πω of the electron-positive hole pair to the surface plasmon. The efficiency of energy transfer from the electron-positive hole pair to the surface plasmon, i.e., a surface plasmon excitation efficiency ηₑ₋ₛ is represented by:

$$\begin{matrix}{η}_{e - s} = \frac{1 / {τ}_{e - s}}{1 / {τ}_{r} + 1 / {τ}_{nr} + 1 / {τ}_{e - s}} \\ = \frac{F / {τ}_{r}}{1 / {τ}_{r} + 1 / {τ}_{nr} + F / {τ}_{e - s}} \\ = \frac{1 / {τ}_{r}}{( 1 / {τ}_{r} + 1 / {τ}_{nr} ) + F + 1 / {τ}_{nr}} \to 1 ( F \to ∞ )\end{matrix} \qquad ( 2 )$$

where 1/τₑ₋ₛ represents the rate of energy transfer from the electron-positive hole pair to the surface plasmon (1/τₑ₋ₛ=F/τᵣ; F represents a coefficient of amplification of the electron-positive hole pair with respect to radiative recombination).

According to expression (2), it is found that, as the amplification coefficient F is increased, the surface plasmon excitation efficiency ηₑ₋ₛ approaches 1 (=100%). By using the Fermi's golden rule, the energy transfer rate τₑ₋ₛ from the electron-positive hole pair to the surface plasmon is represented by:

$${τ}_{e - s} = \frac{2 π}{η} {〈 d \cdot E ( a ) 〉}^{2} ρ ( η ω ) \qquad ( 3 )$$

where d represents a dipole moment when the recombination of the electron-positive hole pair is approximated by an electric dipole, E(a) represents an electric field at an active layer position z=a of the surface plasmon, and ρ(h/2πω) represents the state density of the surface plasmon. Since d may be considered to be a physical property value which is substantially determined by the material, E(a) and ρ(h/2πω) are parameters which can be controlled by a structure of the device.

It is known that the intensity of E(a) becomes maximum at the semiconductor/metal interface z=0, and exponentially decreases with an increase in distance from the interface to the active layer. Therefore, τₑ₋ₛ can be increased by causing the active layer to be closer to the semiconductor/metal interface. ρ(h/2πω) is proportional to the reciprocal dk/dω of the slope of the plasmon ω-k dispersion curve. Therefore, as illustrated in FIG. 17B, ρp(h/2πω) becomes considerably large at ωₛ which the dispersion curve asymptotically approaches. Therefore, if the energy of h/2πω of the electron-positive hole pair, i.e., the band gap energy of the active layer is assumed to be in the vicinity of ηωₛ, τₑ₋ₛ can be caused to be large.

FIG. 18 is a schematic diagram of a conventional LED employing surface plasmons which is disclosed in Document 1. The LED has a structure in which a GaN layer 1002, an InGaN active layer 1003, and a GaN intermediate layer 1004 are successively formed by crystal growth on a sapphire substrate 1001. The active layer 1003 has a photoluminescence (PL) wavelength of 460 nm (i.e., emitted light is blue). A metal 1005 is formed on the intermediate layer 1004. Surface plasmons are generated at an interface of the intermediate layer 1004 and the metal 1005.

In Document 1, in order to increase the amplification coefficient F, the intermediate layer 1004 made of GaN is designed to have a film thickness of 10 nm so as to provide a considerably close semiconductor/metal interface. Also, the band gap energy of 2.7 eV (emitted light wavelength: 460 nm) of the active layer 1003 is set to be in the vicinity of a quantum energy of h/2πωs to 3 eV (equivalent to a wavelength of 410 nm of light in vacuum) of a surface plasmon at an interface of the semiconductor (the GaN intermediate layer 1004) and the metal (Ag) 1005. As a result, the PL emitted light intensity at a peak wavelength is successfully increased to be 14 times larger than that which is obtained when the metal film is not provided.

To drive the semiconductor light emitting device of Document 1, it is necessary to efficiently convert excited surface plasmons into light, which is in turn emitted to the outside of the light emitting device. To cause the surface plasmon to emit light, it is necessary to cause a wave number in a horizontal direction to match that of propagating light due to the translational symmetry in the horizontal direction. However, since the surface plasmons are localized, the horizontal wave number is larger than that of the propagating light.

As a method of causing the surface plasmon to emit light, in Document 1, the metal is vapor-deposited so that it has a thin thickness and a rough metal surface. By the thin metal, surface plasmons occurring at an interface of the semiconductor and the metal and at an interface of the metal and the air are coupled together. The coupled surface plasmons are scattered by the unevenness present at the interface of the metal and the air, so that light is emitted.

### SUMMARY OF THE INVENTION

However, the conventional technique described in Document 1 has difficulty in achieving a high light emission efficiency during current injection for the following reason.

Firstly, in the conventional LED of Document 1, it is difficult to select an electrode material. Although a metal for generating surface plasmons is used as an electrode in this LED, a metal suitable for generation of surface plasmons is not always suitable as an electrode material. For example, when surface plasmons are used in an ultraviolet region, since aluminum (Al) has a higher plasma frequency than that of silver (Ag), Al is suitable for generation of surface plasmons in the ultraviolet region. However, since Al has a low work function, Al is not suitable as an electrode material and is difficult to achieve ohmic contact. As a result, when Al is used in a semiconductor light emitting device, the voltage efficiency is low.

Also, in the conventional LED, it is difficult to improve the efficiency of energy conversion from electron-positive hole pairs into surface plasmons while keeping the performance. In order to efficiently convert energy from electron-positive hole pairs into surface plasmons, a distance between the active layer 1003 and the metal, i.e., a film thickness of the intermediate layer 1004 containing a p-type impurity, needs to be as thin as 100 nm or less. However, when the intermediate layer 1004 is considerably thin, it is difficult to control overflow of electrons from the active layer 1003, resulting in a decrease in efficiency of formation of electron-positive hole pairs. Also, when the intermediate layer 1004 having the p-type impurity is considerably thin, a variation in film thickness of the intermediate layer 1004 is likely to cause a short circuit of the active layer 1003 and the p electrode (the metal 1005), resulting in occurrence of leakage.

Also, in the structure of Document 1, since scattering due to a rough surface is utilized, it is difficult to achieve efficient light emission, resulting in a low efficiency of light emission from surface plasmons.

Also, since light emission cannot be controlled in the structure of the conventional LED, obliquely emitted light is generated. The light is totally reflected at the interface of the semiconductor and the air, so that the light remains inside the semiconductor light emitting device. In addition, surface plasmons occurring at the semiconductor/metal interface and the metal/air interface of the thin metal film are coupled together, so that there is a light component which is emitted from the metal/air interface into the air. Since the light is emitted in a direction exactly opposite to an intended direction, the light cannot be utilized. As a result, the light extraction efficiency remains low.

Thus, in the semiconductor light emitting device of Document 1, although the internal quantum efficiency is increased to 41% from 6% where a metal film is not provided, the light extraction efficiency is estimated to be about 23%. Therefore, the external quantum efficiency remains 8%.

In addition, the LED structure of Document 1 has less ability to dissipate heat. To achieve high ability to dissipate heat, the p electrode needs to be mounted on a mounting substrate made of a material having a high thermal conductivity. When mounting is performed in this manner, heat generated in the active layer 1003 can be easily transferred via the thin intermediate layer 1004 to the mounting substrate. However, in the structure of Document 1, when the p electrode is mounted, a surface of the metal 1005 is adhered via solder to the mounting substrate, so that the unevenness of the metal/air interface is eliminated. Therefore, it is not possible to achieve light emission of surface plasmons due to the unevenness of the interface.

In view of the above description, an object of the present invention is to provide a semiconductor light emitting device having an improved external quantum efficiency and a method for manufacturing the semiconductor light emitting device.

To achieve the object, a first semiconductor light emitting device of the present invention comprises a semiconductor multilayer film including an active layer, in which unevenness is formed in a portion including at least the active layer, and a plasmon generating layer made of a substance having a negative dielectric constant at a frequency of light generated, and buried in the unevenness.

With this configuration, since the plasmon generating layer is buried in the uneven portion including the active layer, an overflow suppressing layer and a contact layer having a sufficient film thickness can be provided on the active layer, and meanwhile, a distance between the active layer and the plasmon generating layer can be sufficiently reduced. Therefore, the rate of energy transfer from electron-positive hole pairs generated in the active layer to surface plasmons generated in the plasmon generating layer can be increased while preventing leakage of electrons from the active layer. As a result, it is possible to improve the internal quantum efficiency of the semiconductor light emitting device.

Examples of the unevenness formed in the semiconductor multilayer film include rods which are formed of a portion of the semiconductor multilayer film including the active layer, holes penetrating through the active layer, and the like.

Note that, if the unevenness has a periodic structure, the horizontal wave number of the surface plasmon can be controlled. As a result, characteristics of light emission from surface plasmons can be controlled. In particular, in a frequency ω-horizontal wave number k_{//} dispersion curve of surface plasmons generated in the plasmon generating layer, if the band gap energy of the active layer is set so that the surface plasmon has substantially k_{//}=0, light from the surface plasmon is emitted in a direction normal to the substrate surface. As a result, the emitted light is not totally reflected at the semiconductor/air interface, and can be obtained outside the semiconductor light emitting device with a high light extraction efficiency. Also, the angle of divergence of light emitted from the semiconductor light emitting device is considerably narrowed, thereby making it possible to output light with high efficiency when the semiconductor light emitting device is coupled with an optical fiber or the like. Note that it is difficult to set the band gap energy of the active layer so that the surface plasmon has exactly k_{//}=0, and therefore, the band gap energy may be set so that the k_{//} of the surface plasmon is in the vicinity of 0.

Also, a substrate which is used to form the semiconductor multilayer film by crystal growth may be eliminated. In this case, the substrate does not need to be transparent. Also, an n electrode can be provided on a rear surface of the semiconductor multilayer film, and a p electrode can be provided on an upper surface of the semiconductor multilayer film, so that the chip area can be reduced as compared to when the substrate is not eliminated.

By further providing an insulating layer between the region of the semiconductor multilayer film in which the unevenness is formed, and the plasmon generating layer, it is possible to prevent leakage of current from the active layer. Note that the insulating layer preferably has a film thickness of 100 nm or less so as to increase the rate of energy transfer from electron-positive hole pairs formed on the active layer to surface plasmons generated in the plasmon generating layer.

Also, the plasmon generating layer may be formed of materials other than metals, and preferably, is formed of a material optimal to the wavelength of emitted light in the active layer. In particular, when ultraviolet light is emitted, the plasmon generating layer is preferably formed of Al. When blue to green light is emitted, the plasmon generating layer is preferably formed of Ag. When red light is emitted, the plasmon generating layer is preferably formed of Au.

Also, the plasmon generating layer may be formed of two or more separate layers. In this case, surface plasmons are generated on a surface of each plasmon generating layer.

A second semiconductor light emitting device of the present invention comprises a semiconductor multilayer film including an active layer, in which unevenness is formed in a portion including at least the active layer, a microsphere made of a substance having a negative dielectric constant at a frequency of light generated, and buried in the unevenness, and a metal layer provided on the semiconductor multilayer film.

With this configuration, since light is emitted using local plasmons generated on a surface of the microsphere, the external quantum efficiency can be improved. The microsphere may be in the shape of a sphere, an ellipse, a rode or the like, or may be hollow or may include another layer.

A method for manufacturing the first semiconductor light emitting device of the present invention comprises the steps of (a) forming a semiconductor multilayer film including an active layer, wherein unevenness is formed in a portion including at least the active layer, and (b) forming a plasmon generating layer made of a substance having a negative dielectric constant at a frequency of light generated, and buried in the unevenness.

With this method, a semiconductor light emitting device having a high external quantum efficiency can be manufactured.

After the step (a) and before the step (b), a step (c) of forming an insulating layer on a region of the semiconductor multilayer film in which the unevenness is formed, may be further provided. The insulating layer may be formed by thermal oxidation of the semiconductor multilayer film, CVD, or the like.

After the step (b), a step (e) of adhering the plasmon generating layer onto the mounting substrate, may be further provided. In this case, the semiconductor multilayer film which is obtained by previously dividing into pieces may be adhered to a mounting substrate. Alternatively, a wafer substrate and the mounting substrate may be adhered together before dividing into pieces. When the division into pieces is performed later, positioning can be more easily performed than when a substrate chip is mounted onto the mounting substrate, and adhesion can be simultaneously performed, thereby making it possible to improve production efficiency.

A method for manufacturing the second semiconductor light emitting device of the present invention comprises the steps of (a) forming a semiconductor multilayer film including an active layer, wherein unevenness is formed in a portion including at least the active layer, (b) placing the substrate in a solution in which a microsphere made of a substance having a negative dielectric constant at a frequency of light generated is dispersed, thereby burying the microsphere in the unevenness, and (c) forming a metal layer provided on the semiconductor multilayer film.

With this method, a semiconductor light emitting device having an improved external light emission efficiency can be produced.

### BRIEF DESCRIPTION OF THE DRAWINGS

FIG. 1A is a perspective view of a semiconductor light emitting device according to a first embodiment of the present invention. FIG. 1B is a cross-sectional view of the semiconductor light emitting device of the first embodiment, taken along a line passing through an n electrode. FIG. 1C is a perspective view of the semiconductor light emitting device of the first embodiment, where a plasmon generating layer and an insulating layer are not illustrated.

FIG. 2A is a graph showing a dispersion relation between a frequency ω and a horizontal wave number k_{//} of surface plasmons in the semiconductor light emitting device of the first embodiment. FIG. 2B is a graph showing a relation between the frequency ω and a state density of surface plasmons.

FIG. 3 is a graph showing the result of calculation of a relation between the frequency ω and a conversion efficiency ηₑ₋ₛ from electron-positive hole pairs to surface plasmons in the semiconductor light emitting device.

FIG. 4 is a graph showing the result of calculation of τₗₒₛₛ in the semiconductor light emitting device, where an interface of the plasmon generating layer and the insulating layer is approximated as being even.

FIG. 5 is a graph showing the result of calculation of ηₛ₋ₚ in the semiconductor light emitting device, where an active layer having an internal quantum efficiency of 30% was used.

FIGS. 6A and 6B are diagrams showing the results of theoretical calculation of the band structure of surface plasmons in the semiconductor light emitting device.

FIGS. 7A and 7B are diagrams showing the results of simulation of photon emission caused by surface plasmons in the semiconductor light emitting device. FIGS. 7C and 7D are diagrams showing electric field distributions at a metal/dielectric substance interface of surface plasmons in modes Γ4 and Γ2, respectively.

FIG. 8 is a graph showing the result of theoretical calculation of the state density of surface plasmons in the semiconductor light emitting device.

FIGS. 9A to 9G are cross-sectional views illustrating a method for manufacturing the semiconductor light emitting device of the first embodiment.

FIG. 10A is a perspective view of a semiconductor light emitting device according to a second embodiment of the present invention. FIG. 10B is a cross-sectional view of the semiconductor light emitting device, taken along a line passing through an n electrode. FIG. 10C is a perspective view of the semiconductor light emitting device of the second embodiment, where a plasmon generating layer and an insulating layer are not illustrated.

FIGS. 11A to 11D are cross-sectional views illustrating a method for manufacturing the semiconductor light emitting device of the second embodiment.

FIG. 12 is a cross-sectional view of a semiconductor light emitting device according to a third embodiment of the present invention.

FIG. 13 is a diagram illustrating a step of arranging microspheres on a semiconductor multilayer film in which an unevenness is formed, in a manufacturing process of the semiconductor light emitting device of the third embodiment.

FIG. 14A is a perspective view of a semiconductor light emitting device according to a fourth embodiment of the present invention. FIG. 14B is a cross-sectional view of the semiconductor light emitting device, taken along a line passing through an n electrode.

FIG. 15 is a cross-sectional view of a semiconductor light emitting device according to a fifth embodiment of the present invention.

FIGS. 16A to 16C are cross-sectional views illustrating a method for manufacturing the semiconductor light emitting device of the fifth embodiment.

FIG. 17A is a diagram for describing surface plasmons. FIG. 17B is a graph for describing surface plasmons.

FIG. 18 is a schematic diagram of a conventional LED employing surface plasmons.

### DETAILED DESCRIPTION OF THE PREFERRED EMBODIMENTS

Hereinafter, embodiments of the present invention will be described with reference to the accompanying drawings.

### First Embodiment

—Configuration of Semiconductor Light Emitting Device—

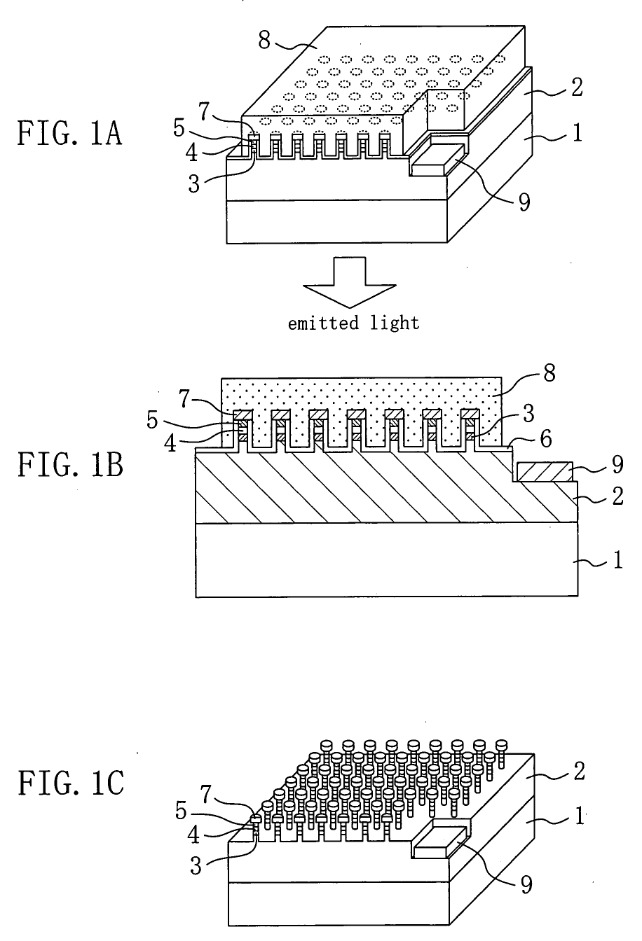

FIG. 1A is a perspective view of a semiconductor light emitting device according to a first embodiment of the present invention. FIG. 1B is a cross-sectional view of the semiconductor light emitting device of this embodiment, taken along a line passing through an n electrode 9. FIG. 1C is a perspective view of the semiconductor light emitting device, where a plasmon generating layer 8 and an insulating layer 6 are not illustrated. A cross-section passing through the n electrode 9 is also illustrated in FIG. 1A for the sake of easy understanding.

As illustrated in FIGS. 1A and 1B, the semiconductor device of this embodiment comprises: a transparent substrate 1 made of sapphire or the like; a semiconductor multilayer film which is formed on the transparent substrate 1 by crystal growth and is made of a GaN compound semiconductor; a p electrode 7 formed on the semiconductor multilayer film; an insulating layer 6 which is formed on at least a side surface of the semiconductor multilayer film and contains, for example, AlGaInOₓ; a plasmon generating layer 8 which is formed on the insulating layer 6, is made of, for example, Al, and has a thickness of 0.5 μm; and an n electrode 9 which is formed on at least a portion of the semiconductor multilayer film.

The semiconductor multilayer film has: an n-type contact layer 2 which is formed on the transparent substrate 1, has a film thickness of 2 μm, and is made of n-type AlGaN; an active layer 3 which is formed on the n-type contact layer 2, includes a multi-quantum well made of AlInGaN, and has a total film thickness of 70 nm; an overflow suppressing layer 4 which is formed on the active layer 3, has a film thickness of 50 nm, and is made of p-type AlGaN; and a p-type contact layer 5 which is formed on the overflow suppressing layer 4, has a film thickness of 150 nm, and is made of p-type GaN. The active layer 3 has a PL peak wavelength of 380 nm.

The p electrode 7 is composed of a Ni layer, a Pt layer and a Au layer, and has a thickness of 80 nm. The n electrode 9 is composed of a Ti layer, an Al layer and a Au layer, and has a film thickness of 300 nm.

In the semiconductor light emitting device of this embodiment, as illustrated in FIG. 1C, an upper portion of the n-type contact layer 2, the active layer 3, the overflow suppressing layer 4, the p-type contact layer 5, and the p electrode 7 constitute rods having a diameter of 150 nm. Therefore, the insulating layer 6 is provided at an upper portion of the n-type contact layer 2, on side surfaces of the active layer 3, the overflow suppressing layer 4 and the p-type contact layer 5, and on an upper surface of the n-type contact layer 2. The insulating layer 6 has a film thickness of about 20 nm.

The plurality of rods composed of the semiconductor multilayer film and the p electrode 7 are provided and arranged periodically, and the interval (between each rod center) is, for example, 325 nm. These rods may be arranged in a two-dimensional periodic manner (e.g., a triangular lattice, a square lattice, etc.) as viewed from the top, and are arranged in a square lattice in the example of FIG. 1A. The plasmon generating layer 8 is buried between these rods. Therefore, the plasmon generating layer 8 contacts the insulating layer 6 covering the side surface of the rod including the active layer 3. Here, in the semiconductor light emitting device of this embodiment, the dielectric constant of the plasmon generating layer 8 is negative and the dielectric constant of the insulating layer 6 is positive at a peak wavelength (380 nm) of the active layer 3.

Also, the p electrodes 7 provided on the p-type contact layer 5 each contact the plasmon generating layer 8, and therefore, are electrically connected to each other, so that a drive current is supplied via the plasmon generating layer 8 to each p electrode 7. The n electrode 9 is provided on a portion of the n-type contact layer 2 whose upper portion is removed (the same side as that on which the plasmon generating layer 8 is provided, as viewed from the n-type contact layer 2).

Positive holes and electrons are injected into the active layer 3 during its operation from the p electrode 7 and the n electrode 9, respectively. As a result, electron-positive hole pairs are generated in the active layer 3, and due to the electron-positive hole pairs, surface plasmons are excited at an interface of the insulating layer 6 and the plasmon generating layer 8. The excited surface plasmons are diffracted by the periodic structure of the rods, so that photons (light) are emitted toward the semiconductor multilayer film. The emitted light propagates through the semiconductor multilayer film, and is emitted through the transparent substrate 1 to the outside of the semiconductor light emitting device (indicated by an arrow in FIG. 1A).

In the semiconductor light emitting device of this embodiment, since the insulating layer 6 is provided between the active layer 3 and the plasmon generating layer 8, it is possible to reduce a distance between the active layer 3 and the plasmon generating layer 8 to improve the rate of energy transfer from the electron-positive hole pair to the surface plasmon, thereby improving the internal quantum efficiency (see expression (3)), and meanwhile, prevent current leakage from the active layer 3. Although the insulating layer 6 is assumed to have a film thickness of 20 nm in the semiconductor light emitting device of this embodiment, the film thickness of the insulating layer 6 is preferably 100 nm or less. This is because, when the film thickness of the insulating layer 6 exceeds 100 nm, the distance between the active layer 3 and the plasmon generating layer 8 is so large that it is difficult to improve the internal quantum efficiency.

Also, in the semiconductor light emitting device of this embodiment, the overflow suppressing layer 4 has a film thickness of 50 nm, which is sufficiently thick, and the p-type contact layer 5 has a film thickness of 150 nm, which is sufficiently thick, thereby making it possible to prevent the overflow of electrons in the active layer 3. Therefore, a decrease in efficiency of generation of electron-positive hole pairs is prevented.

Also, in the semiconductor light emitting device of this embodiment, the p electrode 7 and the plasmon generating layer 8 are separately provided, thereby making it possible to form the plasmon generating layer 8 and the p electrode 7 of materials suitable for respective applications. In this embodiment, since light emitted by the semiconductor light emitting device is ultraviolet light, the plasmon generating layer 8 is made of, for example, Al, while the p electrode 7 is made of a multilayer structure composed of a Ni layer, a Pt layer and a Au layer, which have a large work function. Note that the p electrode 7 has a thickness of 0.5 μm, which is sufficiently large, so that a surface plasmon is not generated at the interface of the p electrode 7 and the plasmon generating layer 8.

Also, in the semiconductor light emitting device of this embodiment, the semiconductor multilayer film has a two-dimensional periodic structure which has an appropriate interval, thereby making it possible to cause the surface plasmon mode to be mode Γ4 or mode Γ5, and therefore, improve the internal quantum efficiency and the light extraction efficiency.

Also, in a frequency ω-horizontal wave number k_{//} dispersion curve of surface plasmons (described below), by setting the band gap energy of the active layer 3 so that the surface plasmon has k_{//}=0, light is emitted from the surface plasmon in a direction normal to the substrate surface. As a result, the emitted light is extracted to the outside of semiconductor light emitting device with high light extraction efficiency without being totally reflected at the semiconductor/air interface. Also, the angle of divergence of light emitted by semiconductor light emitting device can be significantly reduced, thereby making it possible to achieve coupling with optical fibers or the like with high efficiency. These benefits will be described in detail below.

—Operation Mechanism of Semiconductor Light Emitting Device—

The operating mechanism of the semiconductor light emitting device of this embodiment will be hereinafter described in more detail.

As described above, in the semiconductor light emitting device of this embodiment, the plasmon generating layer 8 and the active layer 3 are close to each other via the thin insulating layer 6, so that energy can be transferred at a high rate from electron-positive hole pairs to surface plasmons generated at the interface of the plasmon generating layer 8 and the insulating layer 6.

If the interface of the plasmon generating layer 8 and the insulating layer 6 is approximated as being even, the rate τₑ₋ₛ of energy transfer from electron-positive hole pairs to surface plasmons can be obtained from expression (3).

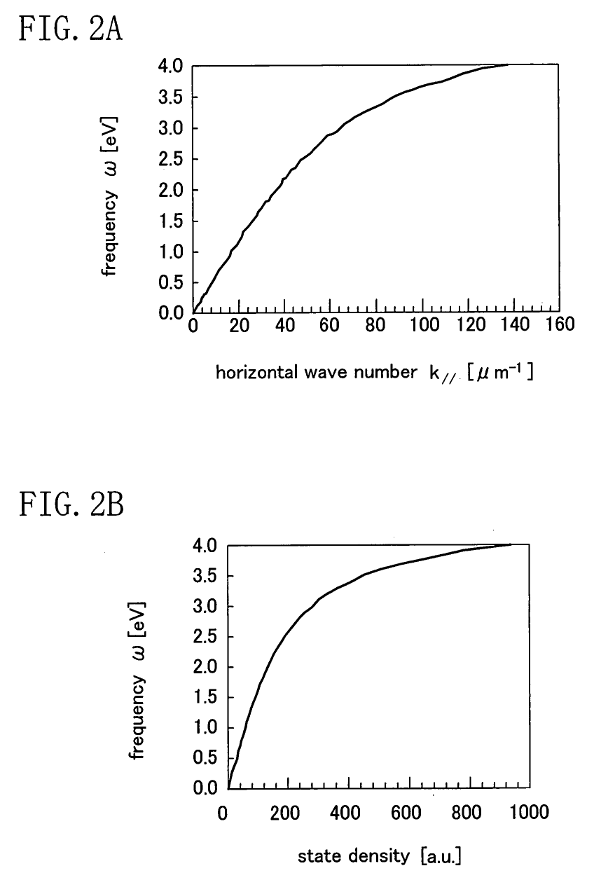

FIG. 2A is a graph showing a dispersion relation between the frequency ω and the horizontal wave number k_{//} of surface plasmons when the plasmon generating layer 8 is made of Al and the insulating layer 6 is made of AlGaInOₓ. FIG. 2B is a graph showing a relation between the frequency ω and the state density of surface plasmons. FIGS. 2A and 2B both show the results of simulation.

According to the results of FIGS. 2A and 2B, it is found that, the higher the frequency ω of surface plasmons, the larger the horizontal wave number k_{//}, and the higher the state density. Note that, in the semiconductor light emitting device of this embodiment, the frequency co is about 3.5 eV, which is equivalent to the band gap energy of the active layer 3.

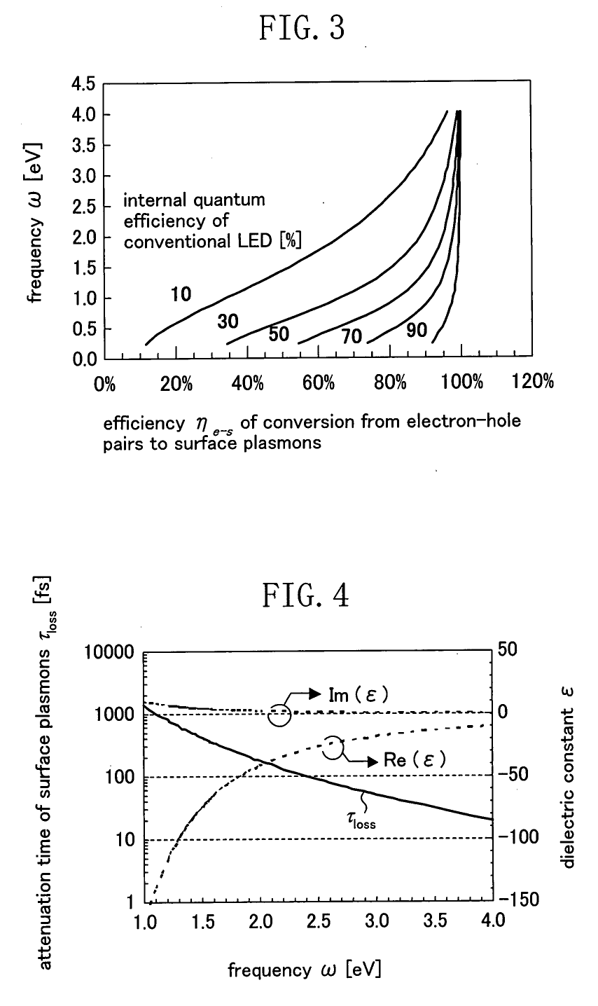

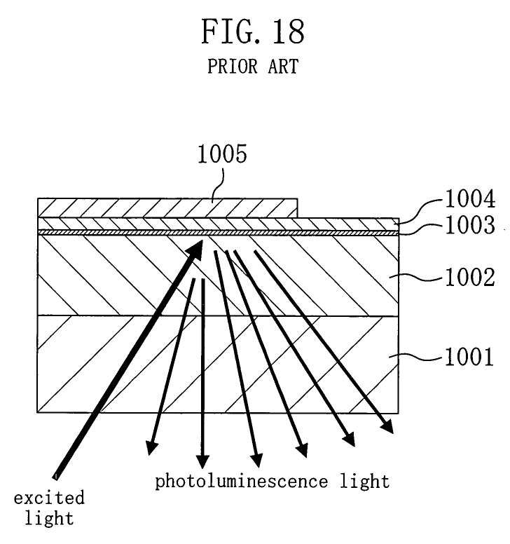

FIG. 3 is a graph showing the result of calculation of a relation between the frequency ω) and the conversion efficiency ηₑ₋ₛ from electron-positive hole pairs to surface plasmons (the excitation efficiency of surface plasmon's) in the semiconductor light emitting device. According to the result of FIG. 3, it is found that, even in the conventional semiconductor light emitting device of FIG. 18 having an internal quantum efficiency of about 30%, since energy is transferred to surface plasmons at a high rate before electron-positive hole pairs lose energy at crystal defects, surface plasmons can be excited with an efficiency of as high as 95%.

The excited surface plasmons have loss before emitting photons, due to scattering in the metal or absorption due to discrete excitation. Therefore, to achieve high-efficiency light emission, it is necessary to increase the efficiency ηₛ₋ₚ of energy transfer from a surface plasmon to a photon. ηₛ₋ₚ can be represented by:

$${η}_{s - p} = \frac{1 / {τ}_{rad}}{1 / {τ}_{rad} + 1 / {τ}_{loss}} \qquad ( 4 )$$

where τ_{rad} represents a time until the surface plasmon emits the photon, and τₗₒₛₛ represents a time until the surface plasmon is attenuated by loss. According to the expression, the smaller the τ_{rad} (the higher the rate of photon emission), or the larger the τₗₒₛₛ (the lower the rate of attenuation), the larger the ηₛ₋ₚ, so that a high-efficiency operation of the semiconductor light emitting device can be achieved.

The emission of photons from surface plasmons is caused by scattering and diffraction due to the unevenness of the interface at which the surface plasmons are generated. According to Document 2 (B. Muller, et. al, Physical Review B, vol. 68, pp. 205415, 2003), the scattering is of Rayleigh scattering, and τ_{rad} is proportional to the fourth power of the reciprocal of the diameter d of the unevenness (the rods in the semiconductor light emitting device of this embodiment). In other words, τ_{rad} is decreased by increasing the diameter d. In the semiconductor light emitting device of this embodiment, the rod made of the semiconductor multilayer film has a diameter of 150 nm. In this case, τ_{rad} can be estimated to be about 20 fs.

According to Document 3 (B. Challener, The Physics of Surface plasmons, pp. 19, 2004, ODS short course seminar materials), when the interface of the plasmon generating layer and the insulating layer is even, the attenuation of surface plasmons is represented by:

$${τ}_{loss} = \frac{2 [ Re ( {ɛ}_{m} ) ]}{ω ɛ \cdot Im ( {ɛ}_{m} )} \qquad ( 5 )$$

where εm represents the dielectric function of a substance used as the plasmon generating layer, and ε represents the dielectric constant of the dielectric substance.

FIG. 4 is a graph showing the result of calculation of τₗₒₛₛ in the semiconductor light emitting device, where the interface of the plasmon generating layer 8 and the insulating layer 6 is even. Note that it is assumed that the plasmon generating layer 8 is made of Al, and the insulating layer 6 is made of AlGaInOₓ. In FIG. 4, a solid line indicates τₗₒₛₛ. According to the result, it is found that, the higher the energy (frequency), the larger the absolute value of the real part of the dielectric constant of the plasmon generating layer 8, the smaller the τₗₒₛₛ (the higher the rate at which the surface plasmon is attenuated). Note that, in the semiconductor light emitting device of this embodiment, since ω is about 3.5 eV, τₗₒₛₛ is estimated to be about 30 fs.

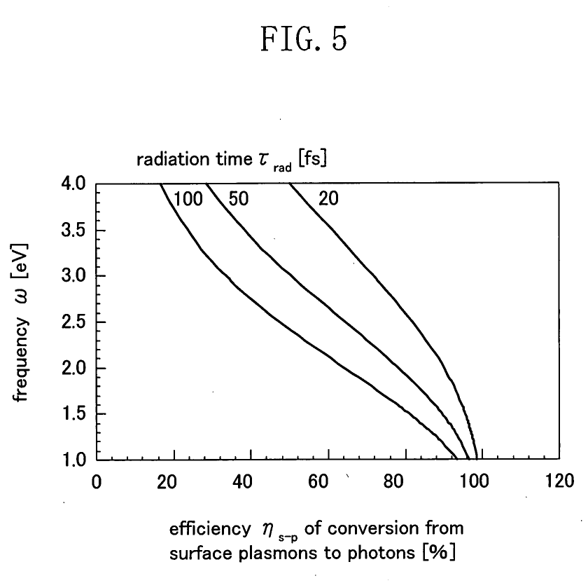

FIG. 5 is a graph showing the result of calculation of ηₛ₋ₚ in the semiconductor light emitting device of this embodiment. FIG. 5 shows cases where τ_{rad} is 20 fs, 50 fs, and 100 fs. According to the result, it is found that, in the semiconductor device of this embodiment, by reducing τ_{rad} to 20 fs, which is sufficiently small (photons are rapidly emitted from surface plasmons), ηₛ₋ₚ can be increased to as large as 67%, i.e., high-efficiency light emission can be achieved.

Therefore, in the semiconductor light emitting device of this embodiment, the internal quantum efficiency including the above-described surface plasmon excitation efficiency is predicted to reach 64% by theoretical calculation. Note that it is assumed that electron-positive hole pairs can be generated from electrons and positive holes injected into the active layer 3 with 100% efficiency.

To estimate the external quantum efficiency, it is necessary to obtain the light extraction efficiency in addition to the internal quantum efficiency. The semiconductor light emitting device of this embodiment is designed as described below so as to achieve a high light extraction efficiency.

Light generated from surface plasmons is emitted toward the semiconductor multilayer film, and is extracted into the air from a rear surface (a surface opposed to a surface on which the semiconductor multilayer film is provided) of the transparent substrate 1. Since the plasmon generating layer 8 is sufficiently thick, the propagation of electromagnetic waves is prohibited inside the plasmon generating layer 8. Therefore, as is different from the semiconductor device of Document 1, light is not emitted from surface plasmons in a direction opposite to the transparent substrate 1. Therefore, it is clear that the light extraction efficiency is higher than that of Document 1. Also, since the direction of light emitted as described below is normal to a major surface of the transparent substrate 1, the light is not totally reflected at the interface in the semiconductor multilayer film or at the interface of the semiconductor multilayer film and the transparent substrate 1, resulting in an even higher light extraction efficiency.

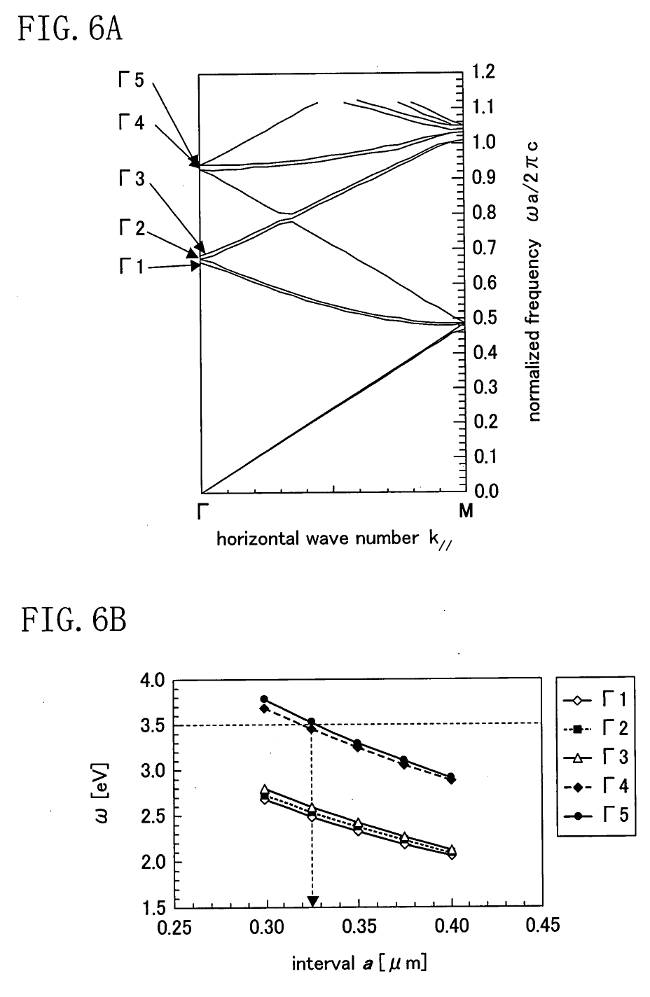

FIGS. 6A and 6B are diagrams showing the results of theoretical calculation of the band structure of surface plasmons in the semiconductor light emitting device of this embodiment. As illustrated in FIG. 6A, the dispersion relation between the frequency ω and the horizontal wave number k_{//} of surface plasmons has a band structure due to multiple diffraction by the periodic structure. In FIG. 6A, the frequency is normalized using an interval a, and only a band structure in a Γ-M direction of k_{//} is displayed. As used herein, the Γ-M direction refers to a direction oblique by 45° to the periodic direction of the square-lattice periodic structure. As described above, during the operation of the semiconductor light emitting device, a surface plasmon is excited in a mode equivalent to the energy of an electron-positive hole pair, i.e., the band gap energy of the active layer 3. Therefore, by appropriately setting the interval a as illustrated in FIG. 6B, the mode of the excited surface plasmon can be selected. In the semiconductor light emitting device of this embodiment, for example, since the interval a of the rods formed of the semiconductor multilayer film is assumed to be 325 nm, the band gap energy of the active layer 3 is 3.5 eV, and surface plasmons in modes Γ4 and Γ5 in the vicinity of the Γ point can be excited. Note that, if the interval a ranges from about 310 nm to about 340 nm, surface plasmons in modes Γ4 and Γ5 can be excited. The acceptable range of the interval a is proportional to the energy distribution width of electron-positive hole pairs generated in the active layer 3.

Emission of photons from surface plasmons are generated while keeping k_{//} due to horizontal discrete translational symmetry. In other words, the k_{//} of an emitted photon is equal to the k_{//} of a surface plasmon. Therefore, the k_{//} of a photon emitted from a surface plasmon in mode Γ4 or Γ5 is zero, i.e., the photon propagates in a direction normal to the major surface of the transparent substrate 1.

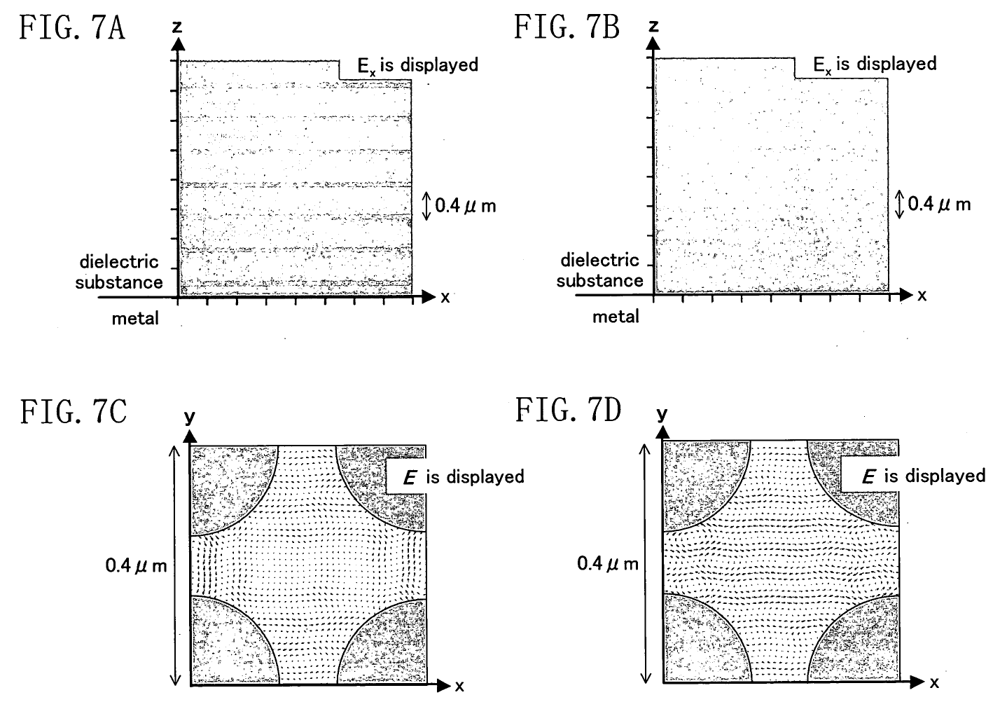

FIGS. 7A and 7B are diagrams showing the results of simulation of photon emission caused by surface plasmons in the semiconductor light emitting device of this embodiment. This simulation was conducted by the Reduced Rayleigh method employed in Document 4 (M. Kretschmann, et. al, Physical Review B, vol. 66, pp. 245408, 2002), where the unevenness of an interface at which surface plasmons are excited is approximated as being small. Note that FIG. 7A shows mode Γ4, and FIG. 7B shows mode Γ2.

In FIG. 7A, lines drawn at predetermined intervals are equipotential lines. Therefore, it is found that there are electromagnetic waves propagating in the normal direction in mode Γ4, i.e., photons are emitted in the normal direction from surface plasmons. In the semiconductor light emitting device of this embodiment, surface plasmons are excited mainly in a mode in the vicinity of Γ4, and therefore, the radiation angle of light emitted from the semiconductor light emitting device is substantially zero, so that narrow light emission is achieved.

On the other hand, it is found that Γ2, which is also a mode in the vicinity of the Γ point, has a weaker level of emission from surface plasmons to photons than that of Γ4 as illustrated in FIG. 7B. The reason for a difference in photon emission efficiency is considered to be that the state density and the electric field distributions of surface plasmons vary, depending on the mode.

FIGS. 7C and 7D are diagrams showing electric field distributions at the metal/dielectric substance interface of surface plasmons in modes Γ4 and Γ2, respectively. Γ4 has substantially a linear electric field as can be seen from FIG. 7C, while Γ2 has a rotation component in an electric field as can be seen from FIG. 7D. The efficiency of emission of photons from surface plasmons also depends on the electric field distribution, and is considered to be proportional to the surface integral of the product of an electric field Espp(x, y) of surface plasmons and an electric field Eph(x, y) of photons at the metal/dielectric substance interface, as the efficiency of coupling between waveguide channels is calculated in classical optics.

∫∫Espp(x,y)·Eph(x,y)dxdy (6)

Since photons propagating in the semiconductor multilayer film has linear lateral deflection, Γ4 has a larger surface integral of the product of the electric fields of surface plasmons and photons than that of Γ2. As a result, it is considered that Γ4 has a higher efficiency of emission of photons from surface plasmons than that of Γ2.

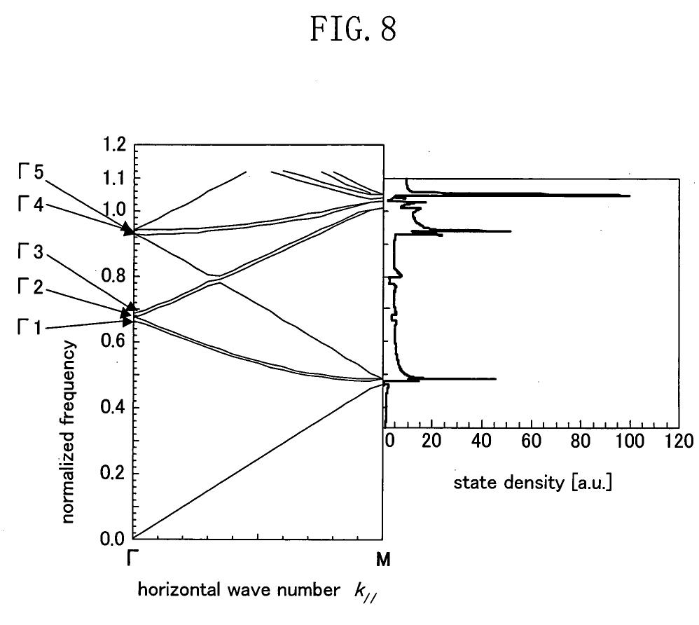

FIG. 8 is a graph showing the result of theoretical calculation of the state density of surface plasmons in the semiconductor light emitting device of this embodiment. As shown in FIG. 8, it is found that Γ4 has a higher state density of surface plasmons than that of Γ2. According to expression (3), Γ4 has a higher rate of energy transfer from electron-positive hole pairs to surface plasmons. Therefore, also in terms of internal quantum efficiency, Γ4 is a more desirable surface plasmon mode than that of Γ2. Therefore, the semiconductor light emitting device of this embodiment can significantly improve the internal quantum efficiency.

Since photons emitted from surface plasmons in mode Γ4 propagate in the normal direction, the photons are not totally reflected at the interface of the semiconductor multilayer film and the transparent substrate or the interface of the transparent substrate and the air. Therefore, the light extraction efficiency can be increased. In conventional LEDs and the semiconductor light emitting device of Document 1, the light emission direction cannot be controlled, so that light is emitted in all directions in space. In this case, when light is incident to the interface of the semiconductor multilayer film and the transparent substrate or the interface of the transparent substrate and the air with a total reflection critical angle or more, the light is totally reflected. Therefore, conventional semiconductor light emitting devices have a low light extraction efficiency.

Note that, also in the semiconductor light emitting device of this embodiment, light undergoes Fresnel reflection at the interface due to a difference in refractive index. Since the Fresnel reflection is as low as several percents, the light extraction efficiency is still high even if two times of reflection loss at the two interfaces are subtracted. Actually, when the semiconductor multilayer film and the transparent substrate 1 have refractive indices of 2.63 (GaN) and 1.79 (sapphire), respectively, as in the semiconductor light emitting device of this embodiment, the light extraction efficiency is 92%. In contrast to this, conventional LEDs and the semiconductor light emitting device of Document 1 have a light extraction efficiency of 20 to 30%. Thus, it is found that the semiconductor light emitting device of this embodiment has a considerably high light extraction efficiency.

As described above, in the semiconductor light emitting device of this embodiment, by appropriately designing the dispersion relation of the frequency ω and the horizontal wave number k_{//} of surface plasmons and the electromagnetic field distribution of surface plasmons, both the internal quantum efficiency and the light extraction efficiency can be improved. Therefore, the semiconductor light emitting device of this embodiment can achieve a high external quantum efficiency.

Specifically, whereas the external quantum efficiency of conventional ultraviolet LEDs is 10% or less, the external quantum efficiency of the semiconductor light emitting device of this embodiment can be improved up to 54%.

—Method for Manufacturing Semiconductor Light Emitting Device—

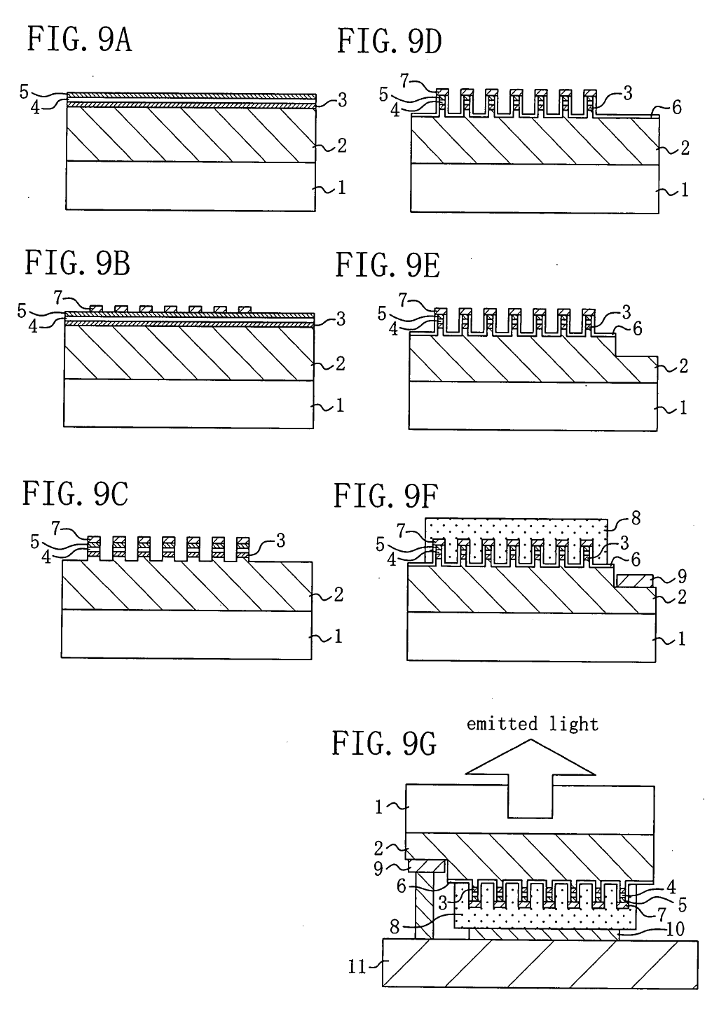

FIGS. 9A to 9G are cross-sectional views illustrating a method for manufacturing the semiconductor light emitting device of the first embodiment of the present invention.

Initially, as illustrated in FIG. 9A, on the transparent substrate 1 made of sapphire, a semiconductor multilayer film which is composed of the n-type contact layer 2 made of n-type AlGaN, the active layer 3 having a multi-quantum well made of AlInGaN, the overflow suppressing layer 4 made of p-type AlGaN, and the p-type contact layer 5 made of p-type GaN, is formed by crystal growth. The crystal growth of the semiconductor multilayer film is performed by MOCVD (Metal-Organic Chemical Vapor Deposition), MBE (Molecular Beam Epitaxy), or the like.

Next, as illustrated in FIG. 9B, the p electrode 7 is fabricated by successively depositing a Ni layer, a Pt layer, and a Au layer on the p-type contact layer 5, and thereafter, shaping the layers into two-dimensional periodic dots (square lattice). Each p electrode 7 is in the shape of a circle having a diameter of about 150 nm as viewed from the top, for example. The p electrodes 7 are arranged at intervals (arrangement interval) of 325 nm.

The materials for the p electrode 7 are deposited by sputtering, vacuum vapor deposition, or the like. To form the dot-shaped structure, the materials for the p electrode 7 is patterned by dry etching or lift-off using a resist patterned by photolithography employing deep-ultraviolet light, electron beam exposure, nano-printing, nano-imprinting, or the like.

Next, as illustrated in FIG. 9C, the semiconductor multilayer film is etched using the p electrode 7 as a mask to form rods, so that at least a side surface of the active layer 3 is exposed. The etching of the semiconductor multilayer film can be performed using: a dry etching technique, such as RIE (Reactive Ion Etching), ion milling, or the like; a wet etching technique, such as photochemical etching employing ultraviolet light, etching employing heated acid/alkali solution, or the like; or the like.

Next, as illustrated in FIG. 9D, the insulating layer 6 is formed on the side surface of the rod. In this embodiment, the insulating layer 6 made of AlGaInOₓ is formed by oxidation of a surface of the semiconductor multilayer film. Here, as a method for oxidizing the semiconductor multilayer film, photochemical oxidation in which the transparent substrate 1 is irradiated with ultraviolet light while being immersed in an acid/alkali solution, plasma oxidation by irradiation with oxygen plasma, thermal oxidation by heating in oxygen gas or water vapor, or the like can be employed. Note that the insulating layer 6 may be formed by CVD or the like.

Next, as illustrated in FIG. 9E, portions of the insulating layer 6 and the n-type contact layer 2 are removed to expose the n-type contact layer 2, and the n electrode 9 composed of a Ti layer, an Al layer and a Au layer is provided on the exposed upper surface of the n-type contact layer 2. As a method for removing portions of the insulating layer 6 and the n-type contact layer 2, and methods for deposition and patterning for the n electrode 9, the above-described general processing methods are employed.

Next, as illustrated in FIG. 9F, a gap between each rod made of the semiconductor multilayer film covered with the insulating layer 6 and the p electrode 7 is filled with the plasmon generating layer 8 made of Al. Al is deposited by vapor deposition, sputtering, CVD, or the like. To fill small concave portions formed by the rods with Al, for example, Al which has been deposited on the semiconductor multilayer film is heated, thereby flowing and changing the shape of Al (reflow technique), or the transparent substrate 1 is heated during deposition of Al so as to improve surface migration of Al atoms and clusters.

In this embodiment, since the wavelength of emitted light is ultraviolet, Al is used as the material for the plasmon generating layer 8. In view of the plasma frequency, when light generated in the active layer 3 is blue (e.g., the material for the active layer 3 is a GaN semiconductor), Ag is desirably used as the material for the plasmon generating layer 8, and when light generated in the active layer 3 is red (e.g., the material for the active layer 3 is a GaAs semiconductor), Au is desirably used as the material for the plasmon generating layer 8. In this case, by using a plating technique, it is possible to easily fill the minute concave portions formed by the rods with Ag or Au.

Next, as illustrated in FIG. 9G, the transparent substrate 1 (wafer) is divided into chips, a p surface (closer to the plasmon generating layer 8) of the chip is bonded via a bump-shaped solder 10 (adhesion layer) to a mounting substrate 11 (flip chip mounting). As a material for the solder 10, AuSn, PbSn, or the like can be employed. AuSn is employed in the semiconductor light emitting device of this embodiment. As the mounting substrate 11, a copper (Cu) substrate or a tungsten (W) substrate having high ability to dissipate heat, an AlN substrate, a Si substrate with an electrostatic breakdown protection circuit, or the like can be employed. The Cu substrate is used in the semiconductor light emitting device of this embodiment.

When the semiconductor light emitting device of this embodiment was subjected to a CW (Continuous Wave) operation, the light output was 30 mW and the external quantum efficiency was 45%, where the drive current was 20 mA. These were close to the above-described theoretically calculated values. Thus, by the above-described method, a semiconductor light emitting device having performance which was substantially the same as that which was designed, was obtained. Note that the reason why these values are deviated from the designed values is considered to be that the following things are not taken into consideration: the efficiency of formation of electron-positive hole pairs in the active layer is expected to be 100%; the internal quantum efficiency is reduced due to surface recombination generated by exposing the active layer during the manufacture process; and light emitted from surface plasmons is resorbed.

On the other hand, characteristics of conventional LEDs having the same semiconductor multilayer film as that of the semiconductor light emitting device of this embodiment surface plasmon were measured. When the drive current was 20 mA, the light output was 5 mW, and the external quantum efficiency was 7%. Assuming that the light extraction efficiency of conventional LEDs is 20%, the internal quantum efficiency of the active layer is 35%, and it is considered that there are a number of crystal defects in the active layer. Note that the internal quantum efficiency of conventional LEDs means an efficiency when photons are emitted directly from electron-positive hole pairs. Even when an active layer having the same composition as that of such an active layer having a number of crystal defects is provided, the semiconductor light emitting device of this embodiment which utilizes surface plasmons can achieve a high external quantum efficiency.

Also, even when the drive current was increased up to 1 A during the CW operation, the light output was not saturated and was increased in proportion to the current, and a light output of 1.4 W was able to be obtained. This means that the semiconductor light emitting device of this embodiment has satisfactory heat dissipation characteristics.

Next, the semiconductor light emitting device of this embodiment which was actually manufactured was estimated in terms of the angle of divergence of emitted light. The result was ±1 degree. Thus, according to the semiconductor light emitting device of this embodiment, the angle of radiation of light was able to be significantly narrowed as compared to conventional LEDs (angle of radiation: ±50 degrees).

Also, the present inventor studied high-speed operation characteristics of conventional LEDs and the semiconductor light emitting device of this embodiment. As a result, under the condition that the drive current was 20 mA, the cutoff frequency of the conventional LED was 100 MHz, while the cutoff frequency of the semiconductor light emitting device of this embodiment was 300 Hz. Thus, it was confirmed that the high-speed operation characteristics of the semiconductor light emitting device of this embodiment are improved as compared to the conventional LEDs.

As described above, with the structure of this embodiment, it is possible to achieve a semiconductor light emitting device having a high external quantum efficiency and a satisfactory directivity of emitted light.

Although a sapphire substrate is used as the transparent substrate 1 in this embodiment, any substrate made of a material transparent to the wavelength of emitted light can be used as the transparent substrate 1. Examples of the transparent substrate 1 include an AlGaN substrate, a sapphire substrate/AlGaN template substrate, a ZnO substrate, and the like.

Also, in the semiconductor light emitting device of this embodiment, at least an upper portion of the semiconductor multilayer film is formed into the shape of rods. If a portion including the active layer 3 of the semiconductor multilayer film is uneven, a distance between the plasmon generating layer 8 filling the unevenness and the active layer 3 can be reduced, the rate of energy transfer from electron-positive hole pairs to surface plasmons can be increased. The unevenness of the semiconductor multilayer film does not necessarily need to have a two-dimensional periodic structure, and for example, may have a one-dimensional periodic structure.

Also, in the semiconductor light emitting device of this embodiment, the insulating layer 6 is provided between the active layer 3 and the plasmon generating layer 8. Alternatively, the insulating layer 6 may not be provided, and a space may be provided between the active layer 3 and the plasmon generating layer 8. In this case, surface plasmons are excited at a surface facing the insulating layer 6 of the plasmon generating layer 8.

Although the semiconductor light emitting device has been described as an LED in this embodiment, the semiconductor light emitting device may be a laser. Also in this case, unevenness is formed on the semiconductor multilayer film including the active layer, and a plasmon generating layer is provided so as to fill the unevenness via an insulating layer, thereby making it possible to improve the external quantum efficiency.

### Second Embodiment

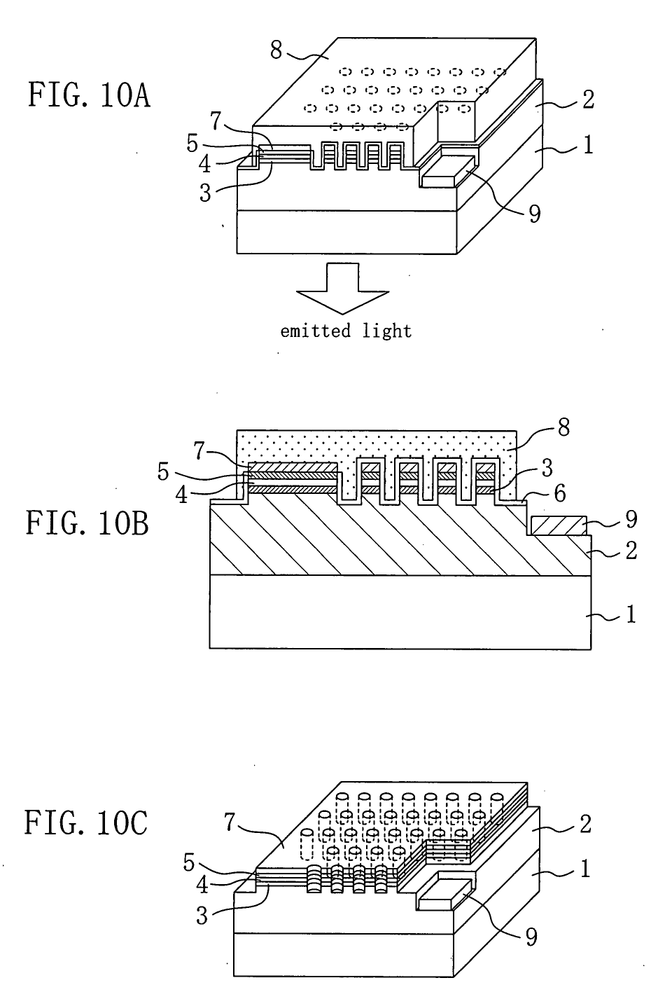

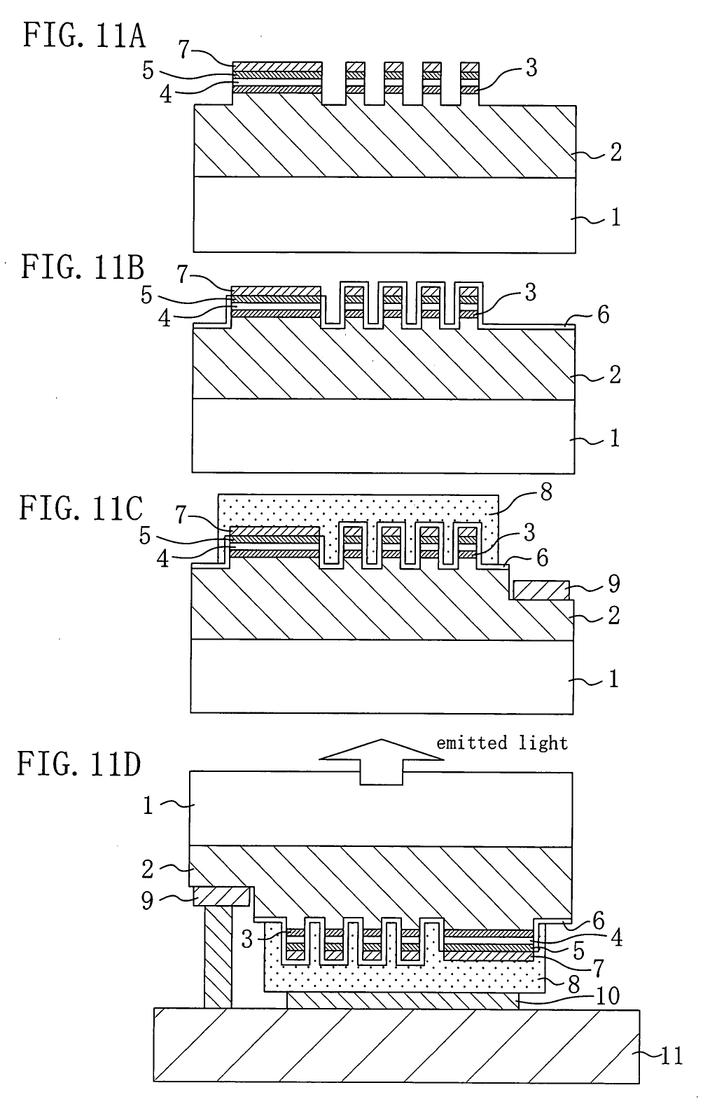

FIG. 10A is a perspective view of a semiconductor light emitting device according to a second embodiment of the present invention. FIG. 10B is a cross-sectional view of the semiconductor light emitting device, taken along a line passing through an n electrode 9. FIG. 10C is a perspective view of the semiconductor light emitting device of this embodiment, where a plasmon generating layer 8 and an insulating layer 6 are not illustrated.

The semiconductor light emitting device of this embodiment is different from the semiconductor light emitting device of the first embodiment in that holes penetrating through at least an active layer 3 of a semiconductor multilayer film are formed and arranged in a two-dimensional periodic manner. For example, the holes each have a diameter of 150 nm, and are arranged in a square lattice having an interval of 325 nm.

The semiconductor light emitting device of this embodiment is also different from the semiconductor light emitting device of the first embodiment in that inner surfaces of the holes as well as a side surface of a p electrode 7 are covered with the insulating layer 6 which has a film thickness of 20 nm and is made of SiO₂. Although the p electrodes 7 formed on the rods are isolated from each other in the semiconductor light emitting device of the first embodiment, the p electrode 7 is integrally formed on the semiconductor multilayer film in the semiconductor light emitting device of this embodiment. Therefore, in the semiconductor light emitting device of this embodiment, as illustrated in FIG. 10B, although the insulating layer 6 covers the upper and side surfaces of the p electrode 7, if only a portion of the p electrode 7 is caused to contact the plasmon generating layer 8, positive holes can be injected into an entire surface of the semiconductor multilayer film. Note that the other members are the same as those of the first semiconductor light emitting device and will not be described.

FIGS. 11A to 11D are cross-sectional views illustrating a method for manufacturing the semiconductor light emitting device of the second embodiment of the present invention. Since the manufacturing method of this embodiment is basically similar to that of the first embodiment, only main points thereof will be described.

Initially, as illustrated in FIG. 11A, a procedure similar to that of the manufacturing method of the first embodiment illustrated in FIGS. 9A to 9C is used to form the semiconductor multilayer film composed of an n-type contact layer 2, the active layer 3, an overflow suppressing layer 4 and a p-type contact layer 5, and the p electrode 7 on the transparent substrate 1. Next, a number of holes having a diameter of 150 nm are formed in the p electrode 7, and thereafter, holes are formed in the semiconductor multilayer film by etching using the p electrode 7 as a mask, thereby exposing a side surface of the active layer 3.

Next, as illustrated in FIG. 11B, the insulating layer 6 is formed which covers the inner surfaces of the holes and an upper surface of the p electrode 7. To cover the surface of such a minute structure, it is desirable to deposit the insulating layer 6 by CVD. By using the method, a highly insulating film can be formed. As a material for the insulating layer 6, an insulating nitride, such as SiN or the like, may be used as well as an insulating oxide, such as SiO₂.

Next, a portion of the insulating layer 6 which is formed in a region for injecting positive holes is removed to expose a portion of the p electrode 7. Next, in a manner similar to the step of FIG. 9E, portions of the insulating layer 6 and the n-type contact layer 2 made of n-type GaN are removed to expose a portion of the n-type contact layer 2. Next, an n electrode 9 is formed on the exposed portion of the n-type contact layer 2. Thereafter, the plasmon generating layer 8 is formed which fills the holes which have been formed in the semiconductor multilayer film and covered with the insulating layer 6. Since the plasmon generating layer 8 is connected to the p electrode 7 at the exposed portion of the insulating layer 6, positive holes can be injected into an entire surface of semiconductor multilayer film from the plasmon generating layer 8 via the p electrode 7.

Next, as illustrated in FIG. 11D, in a manner similar to the step of the first embodiment of FIG. 9G, the transparent substrate 1 is divided into chips, and a surface closer to the plasmon generating layer 8 of the separate chip is bonded to a mounting substrate 11. Thus, the semiconductor light emitting device of this embodiment is fabricated.

Also, in the semiconductor light emitting device of this embodiment, as is similar to the semiconductor light emitting device of the first embodiment, the external quantum efficiency is significantly improved, and the angle of radiation of light is more significantly narrowed than that of conventional LEDs.

### Third Embodiment

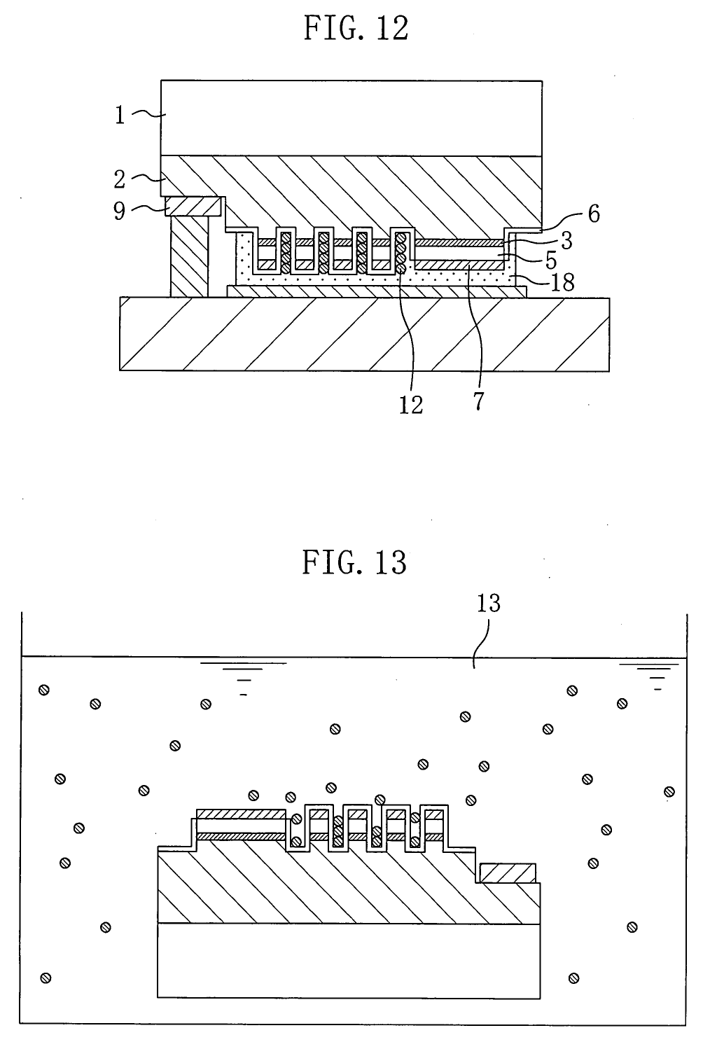

FIG. 12 is a cross-sectional view of a semiconductor light emitting device according to a third embodiment of the present invention.

In the semiconductor light emitting devices of the first and second embodiments, the continuous plasmon generating layer 8 is formed to fill the minute unevenness formed in the semiconductor multilayer film. In contrast to this, as illustrated in FIG. 12, in the semiconductor light emitting device of this embodiment, holes having a diameter of about 150 nm which penetrate through an active layer 3 are formed in a semiconductor multilayer film, and a plurality of microspheres 12 made of Al, Ag, Au or the like are buried inside the hole. In the semiconductor light emitting device of this embodiment, the peak wavelength of emitted light is in an ultraviolet region of 380 nm, and therefore, Al is preferably used as a material for the microsphere 12.

Also, a metal layer 18 which is provided on an insulating layer 6 and a p electrode 7 fills between the microspheres 12, and between the unevenness and the microspheres 12. The material for the metal layer 18 is not limited to those which generate plasmons, and may be a metal so as to supply positive holes to the p electrode 7. Note that the microsphere 12 and the metal layer 18 need to be made of different metal materials.

When the semiconductor light emitting device of this embodiment is operated, local plasmons are generated in the microsphere 12. Therefore, photons emitted from the local plasmons can be utilized. Therefore, as is similar to the semiconductor light emitting devices of the first and second embodiments, the semiconductor light emitting device of this embodiment can exhibit a high external quantum efficiency, and more significantly reduce the angle of divergence of emitted light than that of conventional semiconductor light emitting devices.

Note that the microsphere 12 may be made of a single material, such as Al, Ag, Au or the like, or may be made of a plurality of metal layers (e.g., an inner portion and an outer portion thereof may be made of different metal layers, etc.). Alternatively, a cavity may be formed in the microsphere 12, or an insulator may be provided in the microsphere 12.

When a cavity is formed in the microsphere 12, surface plasmons in different modes can be generated at both an outer surface and an inner surface of the microsphere 12. Also, when the inner and outer portions of the microsphere 12 are made of different materials, surface plasmons can be generated at both an outer surface of the microsphere 12 and an interface of the inner layer and the outer layer. In this case, by adjusting a film thickness of the outer layer, the internal quantum efficiency and the light extraction efficiency can be adjusted as appropriate.

Thus, in the semiconductor light emitting device of this embodiment, since the degree of freedom of designing the structure of the microsphere 12 is large, the external quantum efficiency can be improved and the angle of divergence of emitted light can be narrowed.

Note that the microsphere 12 is not limited to the spherical shape, or may be in the shape of an elliptical sphere, a rod or the like.

Next, a method for manufacturing the semiconductor light emitting device of this embodiment will be briefly described. An exemplary method for fabricating the microsphere 12 is disclosed in, for example, Physical Review letters, volume 93, p. 077402 (2004), and an exemplary method for arranging microspheres is disclosed in, for example, Current Opinion in Colloid & Interface Science, volume 7, p. 204 (2002).

FIG. 13 is a diagram illustrating a step of arranging the microspheres 12 on the semiconductor multilayer film in which an unevenness is formed, in a manufacturing process of the semiconductor light emitting device of the third embodiment.

Initially, by using the same steps as those of FIGS. 11A to 11C, a semiconductor light emitting device is fabricated in which a number of holes are formed in the p electrode 7 and the semiconductor multilayer film. The insulating layer 6 and the n electrode 9 are previously formed in the semiconductor light emitting device.

Next, as illustrated in FIG. 13, the semiconductor light emitting device is immersed in a dispersion solution 13 (e.g., water, an organic solvent, etc.) in which the microspheres 12 made of Al or the like are dispersed, so that the microspheres 12 are placed in the holes formed in the semiconductor multilayer film.

Thereafter, the semiconductor light emitting device is removed from the dispersion solution 13, and the metal layer 18 is formed on the insulating layer 6 by sputtering or the like. Thus, the semiconductor light emitting device of this embodiment is fabricated.

Note that, even when a plurality of rods are formed in the semiconductor multilayer film, local plasmons can be generated by providing the microspheres 12 between each rod.

### Fourth Embodiment

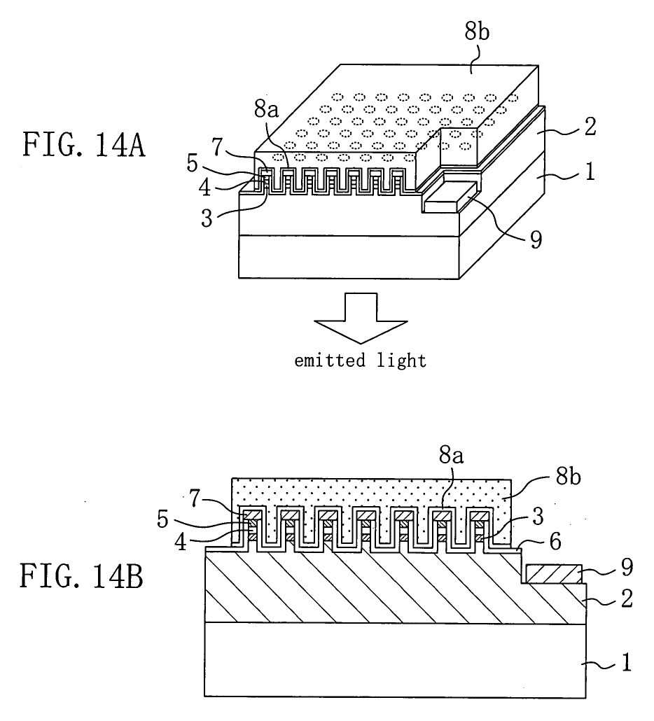

FIG. 14A is a perspective view of a semiconductor light emitting device according to a fourth embodiment of the present invention. FIG. 14B is a cross-sectional view of the semiconductor light emitting device, taken along a line passing through an n electrode 9.

The semiconductor light emitting device of this embodiment is characterized in that a plasmon generating layer is composed of two layers, i.e., a first plasmon generating layer 8a and a second plasmon generating layer 8b. The other parts are the same as those of the semiconductor light emitting device of the first embodiment. The first plasmon generating layer 8a and the second plasmon generating layer 8b are made of any of Al, Ag and Au, and the first plasmon generating layer 8a and the second plasmon generating layer 8b are made of different metals.

In the semiconductor light emitting device of this embodiment, surface plasmons are generated not only at an interface of the first plasmon generating layer 8a and the insulating layer 6, but also at an interface of the first plasmon generating layer 8a and the second plasmon generating layer 8b. With this structure, surface plasmons in different modes can be generated at the respective interfaces. Therefore, by adjusting the interval of the rods as appropriate, the external quantum efficiency can be improved, and in addition, by adjusting a film thickness of the first plasmon generating layer 8a, the external quantum efficiency can be improved. Thus, the degree of freedom of design is increased in the semiconductor light emitting device of this embodiment. Also, the first plasmon generating layer 8a and the second plasmon generating layer 8b have different wavelength of light for effectively generating surface plasmons, thereby making it possible to generate surface plasmons within a broad wavelength range.

Note that the addition of the film thicknesses of the insulating layer 6 and the first plasmon generating layer 8a is preferably 100 nm or less so that a distance between the second plasmon generating layer 8b and the active layer 3 is 100 nm or less.

Also, the semiconductor light emitting device of this embodiment can be easily manufactured by applying the manufacturing method of the first embodiment.

### Fifth Embodiment

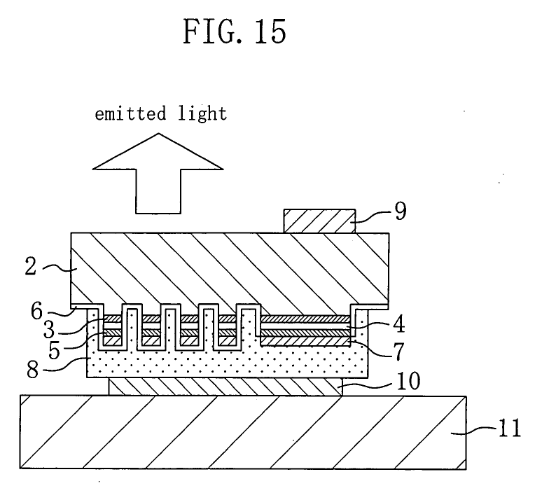

FIG. 15 is a cross-sectional view of a semiconductor light emitting device according to a fifth embodiment of the present invention. The semiconductor light emitting device of this embodiment is an LED which emits blue light. Note that the semiconductor light emitting device of FIG. 15 is turned upside down as compared to the semiconductor light emitting devices of FIG. 1 and the like.

Specifically, the semiconductor light emitting device of this embodiment comprises: a semiconductor multilayer film in which a number of holes having a diameter of 200 nm are formed; a p electrode 7 which is formed on a first major surface (a lower surface in FIG. 15) of the semiconductor multilayer film; an insulating layer 6 which covers a side surface and the first major surface of the semiconductor multilayer film and a lower surface of the p electrode 7; a plasmon generating layer 8 which is provided on a lower surface of the insulating layer 6 and fills the holes in the semiconductor multilayer film; an n electrode 9 which is formed on a second major surface (an upper surface in FIG. 15) of the semiconductor multilayer film; a mounting substrate 11; and a solder 10 which adheres the mounting substrate 11 and the plasmon generating layer 8 together.

The semiconductor multilayer film has: an n-type contact layer 2 which is made of n-type GaN and has a film thickness of 2 μm; an active layer 3 which is formed on the first major surface (the lower surface in FIG. 15) of the n-type contact layer 2, is made of InGaN, has a multi-quantum well whose total film thickness is 80 nm; an overflow suppressing layer 4 which is formed on the first major surface of the active layer 3, has a film thickness of 50 nm, and is made of p-type AlGaN; and a p-type contact layer 5 which is formed on thee first major surface of the overflow suppressing layer 4, has a film thickness of 150 nm, and is made of p-type GaN. The p electrode 7 is composed of a Ni layer, a Pt layer and a Au layer, and has a film thickness of 80 nm. The n electrode 9 is composed of a Ti layer, an Al layer and a Au layer, and has a film thickness of 300 nm.

In the semiconductor light emitting device of this embodiment, the holes formed in the semiconductor multilayer film penetrate at least the active layer 3, and are arranged in a two-dimensional periodic manner as viewed from the top. In the example of FIG. 15, the holes are formed in a square lattice having an interval of 400 nm. The insulating layer 6 which is made of SiO₂ or the like and has a film thickness of 30 nm is formed on inner surfaces of the holes and the lower surface and a side surface of the p electrode 7. Note that the insulating layer 6 is not formed on a portion of the lower surface of the p electrode 7, so that the p electrode 7 and the plasmon generating layer 8 contact each other at the portion.

In the semiconductor light emitting device of this embodiment, the active layer 3 has a PL peak wavelength of 460 nm, and light is emitted from the second major surface (on which the n electrode 9 is formed) of the n-type contact layer 2. The plasmon generating layer 8 is made of a metal which has a negative dielectric constant at a PL peak wavelength of the active layer 3. In this embodiment, the plasmon generating layer 8 is made of Ag.

The semiconductor light emitting device of this embodiment is significantly different from the semiconductor light emitting device of the second embodiment in that the transparent substrate used for crystal growth of the semiconductor multilayer film is removed. With this structure, the substrate used during manufacture may not be transparent, thereby making it possible to more easily achieve crystal growth of the semiconductor multilayer film. Also, since the n electrode 9 is formed on the second major surface (a surface opposed to the major surface on which the active layer 3 is formed) of the n-type contact layer 2, the chip area can be reduced, and electrons can be more easily diffused into an entirety of the active layer 3 than when the n electrode 9 is formed on the first major surface.

A method for manufacturing the semiconductor light emitting device of this embodiment will be hereinafter described.

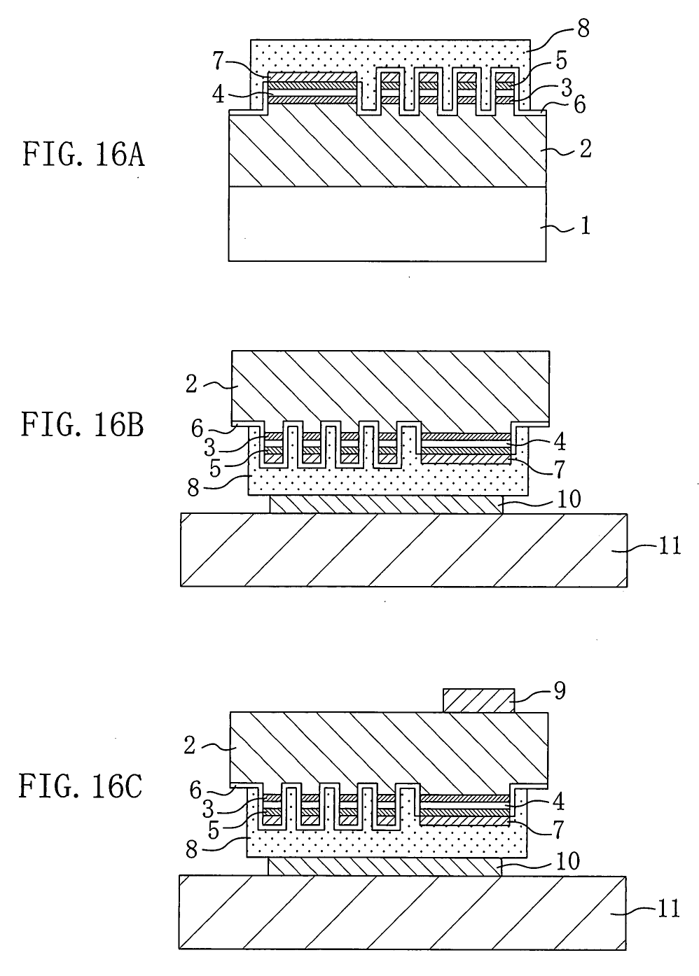

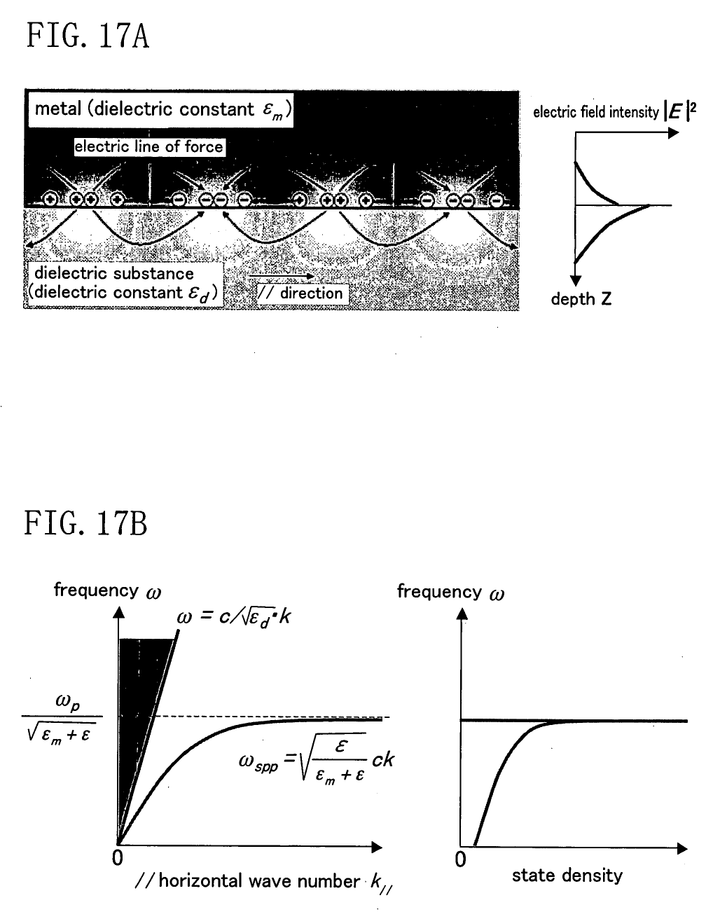

FIGS. 16A to 16C are cross-sectional views illustrating the method for manufacturing the semiconductor light emitting device of the fifth embodiment of the present invention.

Initially, as illustrated in FIG. 16A, by the same steps as those of the second embodiment of FIGS. 11A and 11B, the semiconductor multilayer film and the p electrode 7 are formed on a substrate 14, and thereafter, holes are formed and arranged in a two-dimensional periodic manner in the semiconductor multilayer film, so that a side surface of the active layer 3 is exposed. Next, the insulating layer 6 which covers the inner surfaces of the holes and the side surface and the upper surface of the p electrode 7 is formed. Thereafter, the plasmon generating layer 8 is formed to fill the holes. Note that, since the substrate 14 which is used for crystal growth of the semiconductor multilayer film is removed in a subsequent step, the substrate 14 does not need to be transparent to the wavelength of emitted light. Therefore, the substrate 14 may be made of Si, which is not transparent to the visible region, SiC, which is not transparent to ultraviolet light, or the like. Alternatively, a substrate which is transparent to wavelengths in the ultraviolet to visible regions, such as a sapphire substrate, or an AlN template substrate on a sapphire substrate, may be used. In this embodiment, a Si substrate, which can be expected to have a larger diameter and lower cost, is used as the substrate 14.

Next, as illustrated in FIG. 16B, a solder 10 similar to that of the first embodiment is used to bond the substrate 14 (wafer) on which the semiconductor multilayer film is formed, onto the mounting substrate 11 (wafer). In this case, bonding is performed so that the major surface of the mounting substrate 11 faces the plasmon generating layer 8. The manufacture method of this embodiment is different from that of the first embodiment in that bonding is performed in units of a wafer. Thus, by performing the bonding step in units of a wafer, mounting cost can be reduced. Thereafter, the substrate 14 is removed from the semiconductor light emitting device. The substrate 14 can be removed by wet etching in the case of a Si substrate, dry etching in the case of a SiC substrate, or lift-off in the case of a sapphire substrate. In this embodiment, the substrate 14 which is a Si substrate is removed by wet etching using HF/HNO₃.

Next, as illustrated in FIG. 16C, the n electrode 9 is formed on a rear surface of the n-type contact layer 2 from which the substrate 14 has been removed. Thereafter, the substrate 14 and the mounting substrate 11 (wafers) are diced into chips of the semiconductor light emitting device of this embodiment, though not illustrated.

When the semiconductor light emitting device of this embodiment was subjected to a CW operation, the light output was 25 mW and the external quantum efficiency was 45%, where the drive current was 20 mA. On the other hand, when conventional LEDs without surface plasmons were fabricated using a wafer in which the same semiconductor multilayer film as that of the semiconductor light emitting device of this embodiment was formed, the light output was 4 mW and the external quantum efficiency was 8%, where the drive current was 20 mA. Assuming that the light extraction efficiency of the conventional LED is 20%, the internal quantum efficiency of the active layer of the employed wafer can be estimated to be 40%. It is considered that, since a Si substrate, which has a lattice constant significantly different from that of GaN semiconductors, was employed, there were a number of crystal defects in the active layer. Although the semiconductor wafer having such an active layer containing a number of crystal defects was used, a high external quantum efficiency can be achieved due to surface plasmons.

Although the periodic structure of the semiconductor multilayer film in any of the above-described embodiments have two-dimensional periodic lattice arrangement, a light emission efficiency can be achieved due to a similar surface plasmon/local plasmon effect even if the periodic structure has a two-dimensional triangular lattice arrangement or other lattice arrangements. In the case of a square lattice, light emitted by the semiconductor light emitting device has a circular beam shape due to its symmetry. In the case of other lattice arrangements, the beam shape can be controlled, depending on the symmetry.

The holes may be formed in the semiconductor multilayer film in a one-dimensional periodic manner instead of the two-dimensional periodic manner. When the holes are formed in a one-dimensionally periodic manner, the light emission efficiency is reduced as compared to when the holes are formed in a two-dimensional periodic manner, but a characteristic operation (e.g., an elliptical beam shape of narrow emission in a one-dimensional periodic direction is achieved, etc.) can be achieved.

Also, although, in any of the semiconductor emitted light devices of any of the above-described embodiments, the cases where AlGaInN, which provides the ultraviolet or blue wavelength of emitted light, are employed have been particularly described, the design of the present invention can be applied to a semiconductor light emitting device in which AlGaAs, AlGaIiP or the like is used as a semiconductor of which the active layer is made.

The above-described semiconductor light emitting device of the present invention is useful as a light source for various electrical apparatuses, for example.

What is claimed is:

1. A semiconductor light emitting device comprising:
a semiconductor multilayer film including an active layer, wherein unevenness is formed in a portion including at least the active layer; and
a plasmon generating layer made of a substance having a negative dielectric constant at a frequency of light generated, and buried in the unevenness.

2. The semiconductor light emitting device of claim 1, wherein a plurality of holes penetrating through the active layer are formed in the semiconductor multilayer film, and
the plasmon generating layer is buried in the plurality of holes.

3. The semiconductor light emitting device of claim 2, wherein the plurality of holes are provided and arranged in a one-dimensional periodic manner or in a two-dimensional periodic manner.

4. The semiconductor light emitting device of claim 2, further comprising:
a p electrode provided on the semiconductor multilayer film, wherein the plurality of holes are formed in the p electrode; and
an n electrode contacting the semiconductor multilayer film,
wherein a portion of an upper surface of the p electrode contacts the plasmon generating layer.

5. The semiconductor light emitting device of claim 4, wherein the n electrode is provided on a rear surface of the semiconductor multilayer film.

6. The semiconductor light emitting device of claim 1, wherein a plurality of rods including the active layer are formed in the semiconductor multilayer film, and
the plasmon generating layer is buried between the plurality of rods.

7. The semiconductor light emitting device of claim 6, wherein the plurality of rods are provided and arranged in a one-dimensional periodic manner or in a two-dimensional periodic maimer.

8. The semiconductor light emitting device of claim 6, further comprising:
a p electrode provided on each of the plurality of rods of the semiconductor multilayer film; and
an n electrode contacting the semiconductor multilayer film,
wherein an upper surface of the p electrode contacts the plasmon generating layer.

9. The semiconductor light emitting device of claim 8, wherein the n electrode is provided on a rear surface of the semiconductor multilayer film.

10. The semiconductor light emitting device of claim 1, further comprising:
an insulating layer provided between a region of the semiconductor multilayer film in which the unevenness is formed, and the plasmon generating layer.

11. The semiconductor light emitting device of claim 10, wherein the insulating layer has a film thickness of 100 nm or less.

12. The semiconductor light emitting device of claim 1, wherein the plasmon generating layer has:
a first plasmon generating layer made of a first material; and
a second plasmon generating layer made of a second material different from the first material and provided on the first plasmon generating layer.

13. The semiconductor light emitting device claim 1, further comprising:
a mounting substrate; and
an adhesion layer for adhering a major surface of the mounting substrate and an upper surface of the plasmon generating layer together.

14. The semiconductor light emitting device of claim 1, further comprising:
a substrate provided below the semiconductor multilayer film and transparent to light generated in the active layer.

15. The semiconductor light emitting device of claim 1, wherein, in an energy-horizontal wave number function of a plasmon generated in the plasmon generating layer, an energy when a horizontal wave number is 0 is substantially equal to a band gap energy of the active layer.

16. A semiconductor light emitting device comprising:
a semiconductor multilayer film including an active layer, wherein unevenness is formed in a portion including at least the active layer;
a microsphere made of a substance having a negative dielectric constant at a frequency of light generated, and buried in the unevenness; and
a metal layer provided on the semiconductor multilayer film.

17. The semiconductor light emitting device of claim 16, wherein an outer shape of the microsphere is in the shape of a sphere, an ellipse or a rode.

18. The semiconductor light emitting device of claim 17, wherein the microsphere is hollow.

19. The semiconductor light emitting device of claim 17, wherein the microsphere includes a substance having a negative dielectric constant at the frequency of the light.

20. A method for manufacturing a semiconductor light emitting device, comprising the steps of:
(a) forming a semiconductor multilayer film including an active layer, wherein unevenness is formed in a portion including at least the active layer; and
(b) forming a plasmon generating layer made of a substance having a negative dielectric constant at a frequency of light generated, and buried in the unevenness.

21. The method of claim 20, further comprising, after the step (a):
(c) forming an insulating layer on a region of the semiconductor multilayer film in which the unevenness is formed.

22. The method of claim 21, wherein, in the step (c), the insulating layer is formed by oxidation of the region of the semiconductor multilayer film in which the unevenness is formed.

23. The method of claim 20, further comprising, after the step (b):
(d) removing the substrate from the semiconductor multilayer film.

24. The method of claim 20, further comprising, after the step (b):
(e) adhering the plasmon generating layer onto the mounting substrate.

25. The method of claim 24, further comprising, after the step (e):
(f) dividing the mounting substrate into pieces.

26. A method for manufacturing a semiconductor light emitting device, comprising the steps of:
(a) forming a semiconductor multilayer film including an active layer, wherein unevenness is formed in a portion including at least the active layer;
(b) placing the substrate in a solution in which a microsphere made of a substance having a negative dielectric constant at a frequency of light generated is dispersed, thereby burying the microsphere in the unevenness; and
(c) forming a metal layer provided on the semiconductor multilayer film.

27. The method of claim 26, wherein, in the step (a), a plurality of holes penetrating through the active layer or a plurality of rods including the active layer are formed in the semiconductor multilayer film.
